(19) United States
(12) Patent Application Publication
(10) Pub. No.: US 2024/0172536 A1
(43) Pub. Date: May 23, 2024

(54) DISPLAY APPARATUS

(71) Applicant: SAMSUNG DISPLAY CO., LTD., Yongin-si (KR)

(72) Inventors: Jaeik LIM, Yongin-si (KR); Seongjun LEE, Yongin-si (KR)

(21) Appl. No.: 18/237,044

(22) Filed: Aug. 23, 2023

(30) Foreign Application Priority Data
Nov. 22, 2022 (KR) 10-2022-0157509

(51) Int. Cl. H10K 59/80; H10K 59/40

(52) U.S. Cl. CPC H10K 59/879; H10K 59/40; H10K 59/873

(57) ABSTRACT

A display apparatus includes a substrate, a first light emitter disposed over the substrate, and a first refractive layer patterned to cover and surround the first light emitter in a plan view. The first light emitter has a rectangular shape including a first long side extending in a first direction, a second long side extending in the first direction, and short sides extending in a second direction intersecting the first direction, the first long side includes a first portion and a second portion, the second long side includes a third portion and a fourth portion, and a length of a part of the first refractive layer protruded from the first portion in the second direction in the plan view and a length of a part of the first refractive layer protruded from the second portion in the second direction in the plan view are different from each other.

This application claims priority to Korean Patent Application No. 10-2022-0157509, filed on Nov. 22, 2022, and all the benefits accruing therefrom under 35 U.S.C. § 119, the content of which in its entirety is herein incorporated by reference.

### BACKGROUND

### 1. Field

One or more embodiments relate to a display apparatus, and more particularly, to a display apparatus with improved visibility.

### 2. Description of the Related Art

As the demand for a display apparatus has increased, the need for the display apparatus that may be used for various purposes has also increased. In accordance with this trend, the display apparatus have gradually become larger or thinner, and the need for the display apparatus having accurate and vivid colors while providing larger and thinner display screens has also increased.

### SUMMARY

One or more embodiments include a display apparatus with improved light extraction efficiency.

Additional aspects will be set forth in part in the description which follows and, in part, will be apparent from the description, or may be learned by practice of the presented embodiments of the disclosure.

According to one or more embodiments, a display apparatus includes a substrate, a first light emitter disposed over the substrate, and a first refractive layer patterned to cover and surround the first light emitter in a plan view, where the first light emitter has a rectangular shape including a first long side extending in a first direction, a second long side extending in the first direction, and short sides extending in a second direction intersecting the first direction, the first long side includes a first portion and a second portion, the second long side includes a third portion and a fourth portion, and a length of a part of the first refractive layer protruded from the first portion in the second direction in the plan view and a length of a part of the first refractive layer protruded from the second portion in the second direction in the plan view are different from each other.

According to the present embodiments, a length of a part of the first refractive layer protruded from the third portion in the second direction in the plan view and a length of a part of the first refractive layer protruded from the fourth portion in the second direction in the plan view may be different from each other.

According to the present embodiments, the first light emitter may emit red light.

According to the present embodiments, the display apparatus may further include a second light emitter disposed over the substrate, and the first refractive layer may be further patterned to cover and surround the second light emitter in the plan view.

According to the present embodiments, the second light emitter may emit green light.

According to the present embodiments, the display apparatus may further include two third light emitters disposed over the substrate, and the first refractive layer may further be patterned to cover and surround the two third light emitters in the plan view.

According to the present embodiments, one of the two third light emitters may have a rectangular shape including a third long side extending in the second direction, a fourth long side extending in the second direction, and short sides extending in the first direction, the third long side may include a fifth portion and a sixth portion, the fourth long side may include a seventh portion and an eighth portion, and a length of a part of the first refractive layer protruded from the fifth portion in the first direction in the plan view and a length of a part of the first refractive layer protruded from the sixth portion in the first direction in the plan view may be different from each other.

According to the present embodiments, a length of a part of the first refractive layer protruded from the seventh portion in the first direction in the plan view and a length of a part of the first refractive layer protruded from the eighth portion in the first direction in the plan view may be different from each other.

According to the present embodiments, the two third light emitters may emit blue light.

According to the present embodiments, a thickness of the first refractive layer may be about 1.5 μm to about 5 μm.

According to the present embodiments, an angle between an inclined side surface of the first refractive layer and a layer disposed thereunder may be about 30° to about 90°.

According to the present embodiments, the display apparatus may further include a second refractive layer directly disposed over the first refractive layer.

According to the present embodiments, the first refractive layer and the second refractive layer may have a first refractive index and a second refractive index, respectively, the first refractive index may be greater than the second refractive index, and a difference between the first refractive index and the second refractive index may be about 0.04 to about 1.

According to the present embodiments, the display apparatus may further include three third light emitters disposed over the substrate.

According to one or more embodiments, a display apparatus includes a substrate, a first light emitter disposed over the substrate, an encapsulation layer encapsulating the first light emitter, an input sensing layer disposed over the encapsulation layer and including a first conductive layer and a first touch insulating layer covering the first conductive layer, and a first refractive layer patterned to cover and surround the first light emitter in a plan view, where the first touch insulating layer and the first refractive layer include a same material.

According to the present embodiments, the first light emitter may have a rectangular shape including a first long side extending in a first direction, a second long side extending in the first direction, and short sides extending in a second direction intersecting the first direction, the first long side may include a first portion and a second portion, the second long side may include a third portion and a fourth portion, and a length of a part of the first refractive layer protruded from the first portion in the second direction in the plan view and a length of a part of the first refractive layer protruded from the second portion in the second direction in the plan view may be different from each other.

According to the present embodiments, an end of a portion of the first refractive layer covering and surrounding the first portion of the first long side of the first light emitter in the plan view may contact the first touch insulating layer.

According to the present embodiment, an end of a portion of the first refractive layer covering and surrounding the fourth portion of the second long side of the first light emitter in the plan view may contact the first touch insulating layer.

According to the present embodiments, the display apparatus may further include a second refractive layer directly disposed over the first refractive layer.

According to the present embodiments, the first refractive layer and the second refractive layer may have a first refractive index and a second refractive index, respectively, the first refractive index may be greater than the second refractive index, and a difference between the first refractive index and the second refractive index may be about 0.04 to about 1.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a display apparatus according to an embodiment;

FIG. 2 is a cross-sectional view schematically illustrating a display apparatus according to an embodiment;

FIG. 3 is a plan view schematically illustrating a display apparatus according to an embodiment;

FIGS. 4 and 5 are equivalent circuit diagrams of a pixel that may be included in a display apparatus according to an embodiment;

FIGS. 6A to 6C and 7 are plan views schematically illustrating the arrangement of unit light emitters in a display area according to an embodiment;

FIG. 8 is a cross-sectional view schematically illustrating a display apparatus according to an embodiment; and

FIG. 9 is a cross-sectional view schematically illustrating a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may include various embodiments and modifications, and certain embodiments thereof are illustrated in the drawings and will be described herein in detail. The effects and features of the disclosure and the accomplishing methods thereof will become apparent from the embodiments described below in detail with reference to the accompanying drawings. However, the disclosure is not limited to the embodiments described below and may be embodied in various modes.

Hereinafter, embodiments will be described in detail with reference to the accompanying drawings, and in the following description, like reference numerals will denote like elements and redundant descriptions thereof will be omitted for conciseness.

It will be understood that although terms such as “first” and “second” may be used herein to describe various elements, these elements should not be limited by these terms and these terms are only used to distinguish one element from another element.

As used herein, the singular forms “a,” “an,” and “the” are intended to include the plural forms as well, unless the context clearly indicates otherwise. “About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Also, it will be understood that the terms “comprise,” “include,” and “have” used herein specify the presence of stated features or elements, but do not preclude the presence or addition of one or more other features or elements.

It will be understood that when a layer, region, area, component, or element is referred to as being “on” another layer, region, area, component, or element, it may be “directly on” the other layer, region, area, component, or element or may be “indirectly on” the other layer, region, area, component, or element with one or more intervening layers, regions, areas, components, or elements therebetween.

Sizes of elements in the drawings may be exaggerated for convenience of description. In other words, because the sizes and thicknesses of elements in the drawings are arbitrarily illustrated for convenience of description, the disclosure is not limited thereto.

When a certain embodiment may be implemented differently, a particular process order may be performed differently from the described order. For example, two consecutively described processes may be performed substantially at the same time or may be performed in an order opposite to the described order.

As used herein, “A and/or B” represents the case of A, B, or A and B. Also, “at least one of A and B” represents the case of A, B, or A and B.

It will be understood that when a layer, region, or component is referred to as being “connected to” another layer, region, or component, it may be “directly connected to” the other layer, region, or component and/or may be “indirectly connected to” the other layer, region, or component with one or more intervening layers, regions, or components therebetween. For example, it will be understood that when a layer, region, or component is referred to as being “electrically connected to” another layer, region, or component, it may be “directly electrically connected to” the other layer, region, or component and/or may be “indirectly electrically connected to” the other layer, region, or component with one or more intervening layers, regions, or components therebetween.

The x axis, the y axis, and the z axis are not limited to three axes of the rectangular coordinate system and may be interpreted in a broader sense. For example, the x axis, the y axis, and the z axis may be perpendicular to one another or may represent different directions that are not perpendicular to one another.

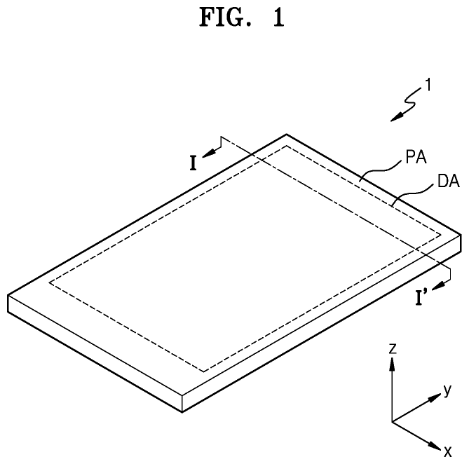

FIG. 1 is a perspective view schematically illustrating a display apparatus according to an embodiment.

Referring to FIG. 1, a display apparatus 1 according to an embodiment may include a display area DA and a peripheral area PA. The peripheral area PA may be arranged outside the display area DA to surround the display area DA. Various lines for transmitting electrical signals to be applied to the display area DA, and a driving circuit unit may be located in the peripheral area PA. The display apparatus 1 may provide a certain image by using light emitted from a plurality of pixels arranged in the display area DA. Although not illustrated, the display apparatus 1 may be bent by including a bending area in a partial area of the peripheral area PA.

The display apparatus 1 may be a display apparatus such as an organic light emitting display apparatus, an inorganic light emitting display apparatus (or an inorganic EL display apparatus), or a quantum dot light emitting display apparatus. Hereinafter, an organic light emitting display apparatus will be described as an example. The display apparatus 1 may be implemented as various electronic apparatuses such as mobile phones, notebook computers, or smart watches.

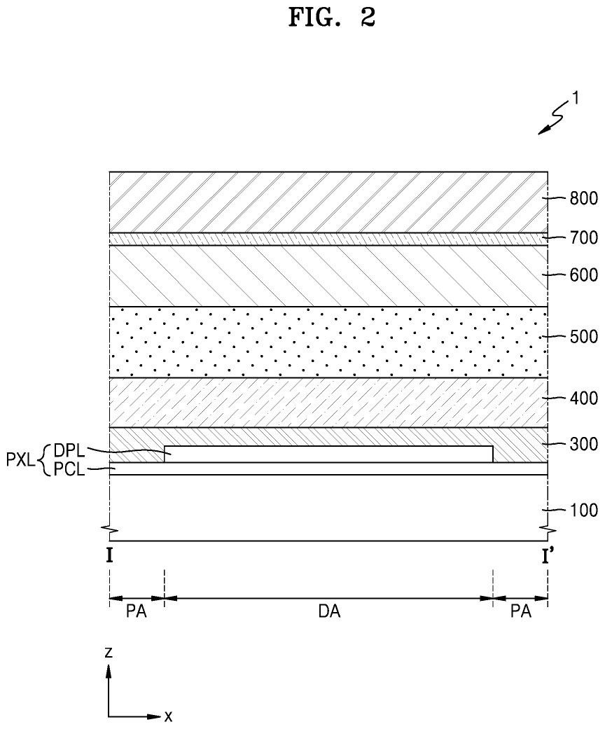

FIG. 2 is a cross-sectional view schematically illustrating a display apparatus according to an embodiment. More particularly, FIG. 2 corresponds to a cross-sectional view of the display apparatus taken along line I-I′ of FIG. 1.

Referring to FIG. 2, the display apparatus 1 may include a substrate 100, a pixel layer PXL over the substrate 100, an encapsulation layer 300 encapsulating the pixel layer PXL, a refractive layer 500 over the encapsulation layer 300, a polarization layer 600 over the refractive layer 500, an adhesive layer 700, and a window 800 that are sequentially stacked in a thickness direction (z direction).

The substrate 100 may include a glass material or may include a polymer resin. In an embodiment, for example, the substrate 100 may include a glass material containing SiO₂ as a main component or may include various materials having flexible or bendable characteristics, for example, a resin such as reinforced plastic. Although not illustrated, the substrate 100 may be bent by including a bending area in a partial area of the peripheral area PA.

The pixel circuit layer PCL may be disposed over the substrate 100. The pixel layer PXL may include a display device layer DPL including display devices arranged in each pixel and a pixel circuit layer PCL including a pixel circuit and insulating layers arranged in each pixel. The display device layer DPL may be disposed over the pixel circuit layer PCL, and a plurality of insulating layers may be arranged between the pixel circuit and the display device. Some lines and insulating layers of the pixel circuit layer PCL may extend to the peripheral area PA.

The encapsulation layer 300 may be a thin film encapsulation layer. The thin film encapsulation layer may include at least one inorganic encapsulation layer and at least one organic encapsulation layer. When the display apparatus 1 includes the substrate 100 including a polymer resin and the encapsulation layer 300 of a thin film encapsulation layer including an inorganic encapsulation layer and an organic encapsulation layer, the flexibility of the display apparatus 1 may be improved.

The refractive layer 500 may adjust the path of light emitted from the display device of the display device layer DPL and may improve the light emission efficiency of the display apparatus 1. As described below, the refractive layer 500 may increase the light extraction efficiency of the display apparatus 1 by changing the path of light emitted from the display device.

The polarization layer 600 may transmit only light vibrating in the same direction as a polarization axis among the light emitted from the display device of the display device layer DPL and may absorb or reflect light vibrating in other directions. The polarization layer 600 may include a phase retarder and/or a polarizer. Also, the polarization layer 600 may include a black matrix and/or a color filter. Although not illustrated, the refractive layer 500 and the polarization layer 600 may be adhered by an adhesive such as an optically clear adhesive (“OCA”).

The window 800 may be disposed over the polarization layer 600, and the adhesive layer 700 such as an optically clear adhesive (OCA) may be arranged therebetween.

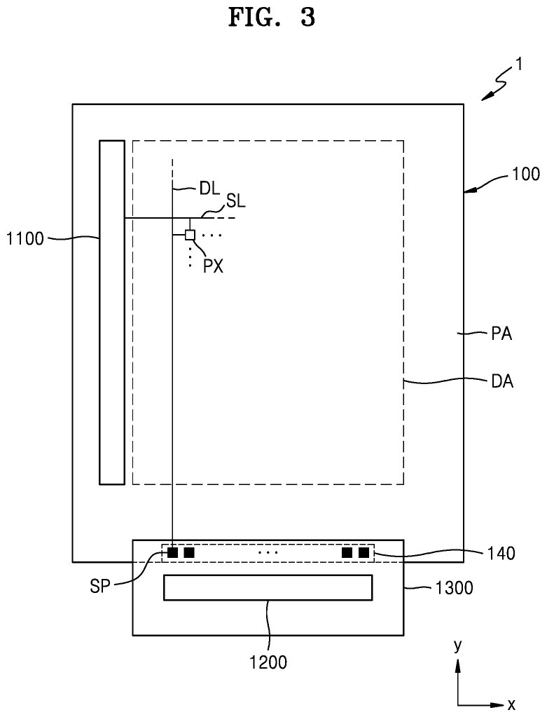

FIG. 3 is a plan view schematically illustrating a display apparatus according to an embodiment. As used herein, the “plan view” is a view in z direction.

Referring to FIG. 3, the substrate 100 may include a display area DA and a peripheral area PA. The peripheral area PA may be located outside the display area DA and may surround the display area DA.

A plurality of pixels PX arranged in a certain pattern in a first direction (x direction or row direction) and a second direction (y direction or column direction) may be included in the display area DA over the substrate 100.

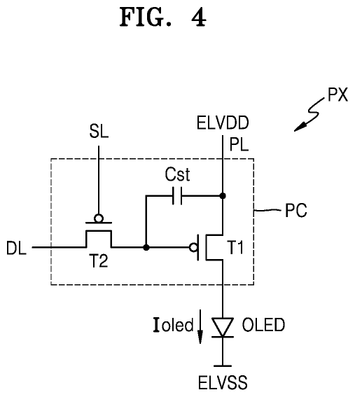

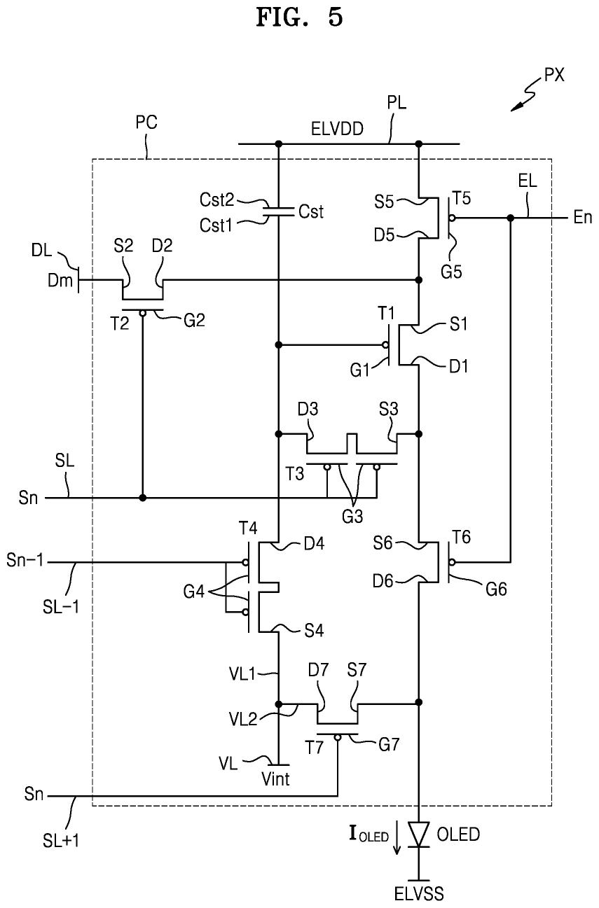

A scan driver 1100 providing a scan signal to each pixel PX, a data driver 1200 providing a data signal to each pixel PX, main power lines (not illustrated) for providing a first power voltage ELVDD (see FIGS. 4 and 5) and a second power voltage ELVSS (see FIGS. 4 and 5), and/or the like may be arranged in the peripheral area PA over the substrate 100. A pad unit 140 in which a plurality of signal pads SP connected to a data line DL are arranged may be located in the peripheral area PA over the substrate 100.

The scan driver 1100 may include an oxide semiconductor TFT gate driver circuit (“OSG”) or an amorphous silicon TFT gate driver circuit (“ASG”). FIG. 3 illustrates an example in which the scan driver 1100 is arranged adjacent to one side of the substrate 100; however, according to some embodiments, the scan driver 1100 may be arranged adjacent to each of two facing sides of the substrate 100.

FIG. 3 illustrates a chip-on-film (“COF”) form in which the data driver 1200 is disposed over a film 1300 electrically connected to the signal pads SP disposed over the substrate 100. According to other embodiments, the data driver 1200 may be directly disposed over the substrate 100 in a chip-on-glass (“COG”) or chip-on-plastic (“COP”) form. The data driver 1200 may be electrically connected to a flexible printed circuit board (“FPCB”).

FIGS. 4 and 5 are equivalent circuit diagrams of a pixel that may be included in a display apparatus according to an embodiment.

Referring to FIG. 4, a pixel PX may include a pixel circuit PC connected to a scan line SL and a data line DL and a display device connected to the pixel circuit PC. The pixel circuit PC may include a transistor and a storage capacitor, and the display device may include an organic light emitting diode OLED.

The pixel circuit PC may include a first thin film transistor T1, a second thin film transistor T2, and a storage capacitor Cst. Each pixel PX may emit, for example, red, green, blue, or white light through the organic light emitting diode OLED. The first thin film transistor T1 and the second thin film transistor T2 may be implemented as a transistor.

The second thin film transistor T2 may be a switching transistor and may be connected to the scan line SL and the data line DL. The second thin film transistor T2 may be configured to transmit a data signal input from the data line DL to the first thin film transistor T1 according to a scan signal input from the scan line SL. The storage capacitor Cst may be connected to the second thin film transistor T2 and a driving voltage line PL and may be configured to store a voltage corresponding to the difference between a voltage corresponding to the data signal received from the second thin film transistor T2 and a first power voltage ELVDD supplied to the driving voltage line PL.

The first thin film transistor T1 may be a driving thin film transistor and may be connected to the driving voltage line PL and the storage capacitor Cst. The first thin film transistor T1 may control a driving current ked flowing from the driving voltage line PL through the organic light emitting diode OLED, in response to a voltage value stored in the storage capacitor Cst.

The organic light emitting diode OLED may emit light with a certain brightness according to the driving current I_{oled}. The organic light emitting diode OLED may include a pixel electrode, an opposite electrode, and an emission layer including an intermediate layer between the pixel electrode and the opposite electrode. The opposite electrode of the organic light emitting diode OLED may be supplied with a second power voltage ELVSS.

FIG. 4 illustrates that the pixel circuit PC includes two thin film transistors and one storage capacitor; however, the disclosure is not limited thereto. The number of thin film transistors and the number of storage capacitors may be variously modified according to the design of the pixel circuit PC.

As another example, referring to FIG. 5, a pixel PX may include a pixel circuit PC and an organic light emitting diode OLED connected to the pixel circuit PC.

As illustrated in FIG. 5, the pixel circuit PC may include a plurality of thin film transistors T1 to T7 and a storage capacitor Cst. The thin film transistors T1 to T7 and the storage capacitor Cst may be connected to signal lines SL, SL−1, SL+1, EL, and DL, a first initialization voltage line VL1, a second initialization voltage line VL2, and a driving voltage line PL.

The signal lines SL, SL−1, SL+1, EL, and DL may include a scan line SL configured to transmit a scan signal Sn, a previous scan line SL−1 configured to transmit a previous scan signal Sn−1 to a first initialization thin film transistor T4, a next scan line SL+1 configured to transmit a scan signal Sn to a second initialization thin film transistor T7, an emission control line EL configured to transmit an emission control signal En to an operation control thin film transistor T5 and an emission control thin film transistor T6, and a data line DL intersecting the scan line SL and configured to transmit a data signal Dm. The driving voltage line PL may be configured to transmit a driving voltage ELVDD to a driving thin film transistor T1, the first initialization voltage line VL1 may be configured to transmit an initialization voltage Vint to the first initialization thin film transistor T4, and the second initialization voltage line VL2 may be configured to transmit an initialization voltage Vint to the second initialization thin film transistor T7.

A driving gate electrode G1 of the driving thin film transistor T1 may be connected to a lower electrode Cst1 of the storage capacitor Cst, a driving source electrode S1 of the driving thin film transistor T1 may be connected to the driving voltage line PL via the operation control thin film transistor T5, and a driving drain electrode D1 of the driving thin film transistor T1 may be electrically connected to a pixel electrode of the organic light emitting diode OLED via the emission control thin film transistor T6. The driving thin film transistor T1 may receive the data signal Dm according to a switching operation of a switching thin film transistor T2 and supply a driving current I_{OLED} to the organic light emitting diode OLED.

A switching gate electrode G2 of the switching thin film transistor T2 may be connected to the scan line SL, a switching source electrode S2 of the switching thin film transistor T2 may be connected to the data line DL, and a switching drain electrode D2 of the switching thin film transistor T2 may be connected to the driving source electrode S1 of the driving thin film transistor T1 and connected to the driving voltage line PL via the operation control thin film transistor T5. The switching thin film transistor T2 may perform a switching operation of transmitting the data signal Dm received through the data line DL to the driving source electrode S1 of the driving thin film transistor T1 by being turned on according to the scan signal Sn received through the scan line SL.

A compensation gate electrode G3 of a compensation thin film transistor T3 may be connected to the scan line SL, a compensation source electrode S3 of the compensation thin film transistor T3 may be connected to the driving drain electrode D1 of the driving thin film transistor T1 and connected to the pixel electrode of the organic light emitting device OLED via the emission control thin film transistor T6, and a compensation drain electrode D3 of the compensation thin film transistor T3 may be connected to the lower electrode Cst1 of the storage capacitor Cst, a first initialization drain electrode D4 of the first initialization thin film transistor T4, and the driving gate electrode G1 of the driving thin film transistor T1. The compensation thin film transistor T3 may be turned on according to the scan signal Sn received through the scan line SL, to electrically connect the driving gate electrode G1 with the driving drain electrode D1 of the driving thin film transistor T1 to diode-connect the driving thin film transistor T1.

A first initialization gate electrode G4 of the first initialization thin film transistor T4 may be connected to the previous scan line SL−1, a first initialization source electrode S4 of the first initialization thin film transistor T4 may be connected to the first initialization voltage line VL1, and the first initialization drain electrode D4 of the first initialization thin film transistor T4 may be connected to the lower electrode Cst1 of the storage capacitor Cst, the compensation drain electrode D3 of the compensation thin film transistor T3, and the driving gate electrode G1 of the driving thin film transistor T1. The first initialization thin film transistor T4 may perform an initialization operation of initializing the voltage of the driving gate electrode G1 of the driving thin film transistor T1 by transmitting the initialization voltage Vint to the driving gate electrode G1 of the driving thin film transistor T1 by being turned on according to the previous scan signal Sn−1 received through the previous scan line SL−1.

An operation control gate electrode G5 of the operation control thin film transistor T5 may be connected to the emission control line EL, an operation control source electrode S5 of the operation control thin film transistor T5 may be connected to the driving voltage line PL, and an operation control drain electrode D5 of the operation control thin film transistor T5 may be connected to the driving source electrode S1 of the driving thin film transistor T1 and the switching drain electrode D2 of the switching thin film transistor T2.

An emission control gate electrode G6 of the emission control thin film transistor T6 may be connected to the emission control line EL, an emission control source electrode S6 of the emission control thin film transistor T6 may be connected to the driving drain electrode D1 of the driving thin film transistor T1 and the compensation source electrode S3 of the compensation thin film transistor T3, and an emission control drain electrode D6 of the emission control thin film transistor T6 may be electrically connected to a second initialization source electrode S7 of the second initialization thin film transistor T7 and the pixel electrode of the organic light emitting diode OLED.

The operation control thin film transistor T5 and the emission control thin film transistor T6 may be simultaneously turned on according to the emission control signal En received through the emission control line EL, such that the driving voltage ELVDD may be transmitted to the organic light emitting diode OLED and thus the driving current I_{OLED} may flow through the organic light emitting diode OLED.

A second initialization gate electrode G7 of the second initialization thin film transistor T7 may be connected to the next scan line SL+1, the second initialization source electrode S7 of the second initialization thin film transistor T7 may be connected to the emission control drain electrode D6 of the emission control thin film transistor T6 and the pixel electrode of the organic light emitting diode OLED, and a second initialization drain electrode D7 of the second initialization thin film transistor T7 may be connected to the second initialization voltage line VL2.

Moreover, because the scan line SL and the next scan line SL+1 are electrically connected to each other, the same scan signal Sn may be applied to the scan line SL and the next scan line SL+1. Thus, the second initialization thin film transistor T7 may perform an operation of initializing the pixel electrode of the organic light emitting diode OLED by being turned on according to the scan signal Sn received through the next scan line SL+1.

An upper electrode Cst2 of the storage capacitor Cst may be connected to the driving voltage line PL, and a common electrode of the organic light emitting diode OLED may be connected to a common voltage ELVSS. Accordingly, the organic light emitting diode OLED may receive the driving current I_{OLED} from the driving thin film transistor T1 to emit light to display an image.

FIG. 5 illustrates that the compensation thin film transistor T3 and the first initialization thin film transistor T4 have a dual gate electrode; however, the compensation thin film transistor T3 and the first initialization thin film transistor T4 may have a single gate electrode.

Also, FIG. 5 illustrates the structure of one pixel circuit PC; however, a plurality of pixels PX having the same pixel circuit PC may be arranged to form a plurality of rows and in this case, the first initialization voltage line VL1, the previous scan line SL−1, the second initialization voltage line VL2, and the next scan line SL+1 may be shared by adjacent pixels.

In an embodiment, for example, the first initialization voltage line VL1 and the previous scan line SL−1 may be electrically connected to a second initialization thin film transistor of another pixel circuit PC arranged in the second direction (y direction). Thus, a previous scan signal applied to the previous scan line SL−1 may be transmitted as a next scan signal to the second initialization thin film transistor of the other pixel circuit PC. Likewise, the second initialization voltage line VL2 and the next scan line SL+1 may be electrically connected to a first initialization thin film transistor of another pixel circuit PC arranged adjacent thereto in the second direction (y direction), to transmit a previous scan signal and an initialization voltage thereto.

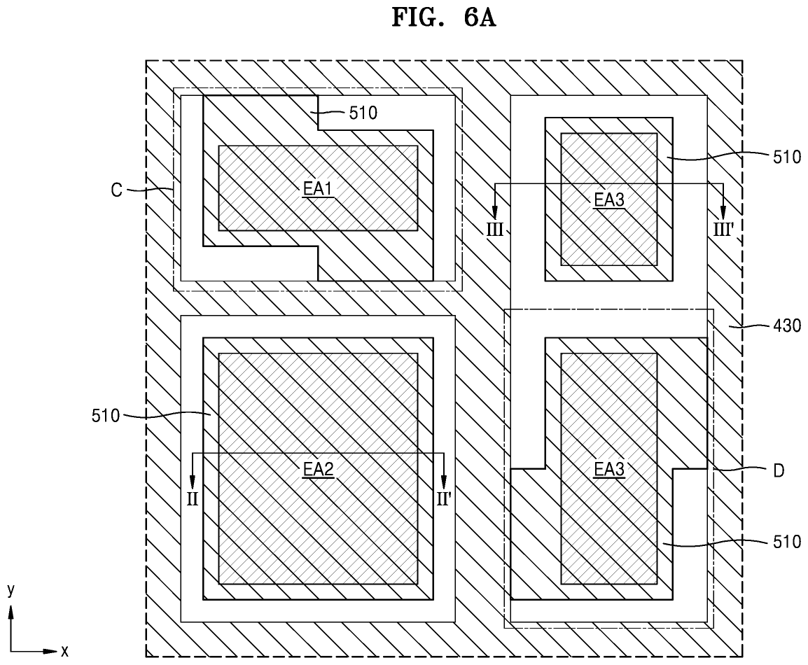

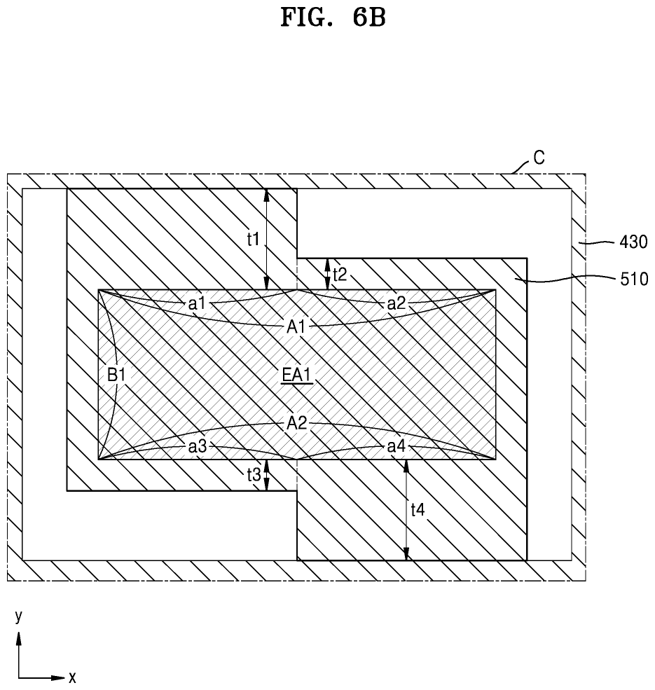

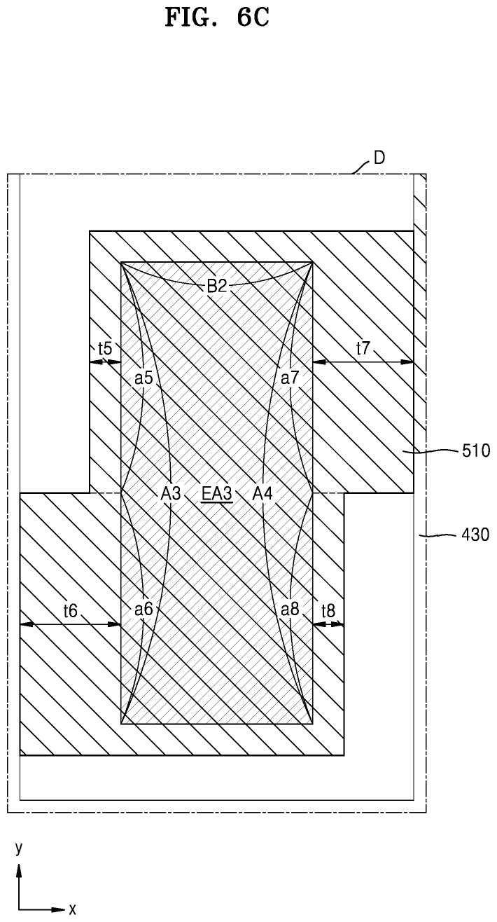

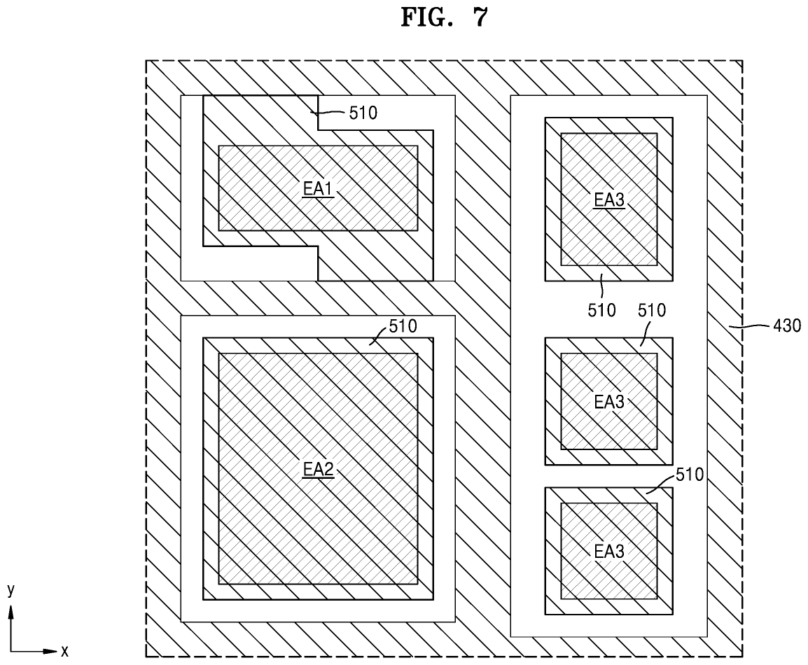

FIGS. 6A to 6C and 7 are plan views schematically illustrating the arrangement of unit light emitters in a display area according to an embodiment. FIGS. 6B and 6C are enlarged cross-sectional views schematically illustrating region C and region D of FIG. 6A, respectively.

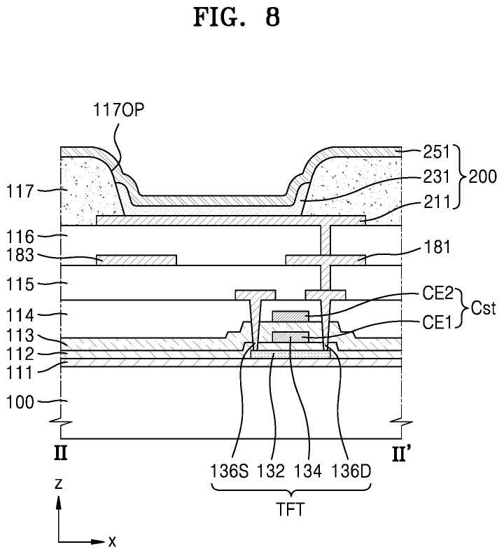

As described above, pixels PX may be arranged in a certain arrangement in the display area DA of the display apparatus 1. Each of the pixels PX (see FIG. 3) may include a pixel circuit PC (see FIG. 4) and an organic light emitting diode OLED (see FIG. 4). The organic light emitting diode OLED may include a pixel electrode 211 (see FIG. 8), an intermediate layer 231 (see FIG. 8), and an opposite electrode 251 (see FIG. 8), and a light emitter EA of the organic light emitting diode OLED may be an area in which the intermediate layer 231 is arranged and may be defined by an opening 1170P of a pixel definition layer 117.

Referring to FIGS. 6A to 6C and FIG. 7, a portion of the arrangement of light emitters EA of the pixels PX in a certain arrangement in the display area DA is schematically illustrated. The pixels may include a first pixel, a second pixel, and a third pixel. The light emitter EA may include a first light emitter EA1, a second light emitter EA2, and a third light emitter EA3. The first light emitter EA1 may be a light emitter of the first pixel, the second light emitter EA2 may be a light emitter of the second pixel, and the third light emitter EA3 may be a light emitter of the third pixel. The first pixel, the second pixel, and the third pixel may emit light of different colors, respectively. In other words, the first light emitter EA1, the second light emitter EA2, and the third light emitter EA3 may emit light of different colors, respectively. In an embodiment, for example, the first light emitter EA1 may emit red light, the second light emitter EA2 may emit green light, and the third light emitter EA3 may emit blue light.

In an embodiment, the first light emitter EA1, the second light emitter EA2, and the third light emitter EA3 may form a unit light emitter. FIG. 6A to 6C and FIG. 7 schematically illustrate the arrangement of the unit light emitter. As illustrated in FIG. 6A, the unit light emitter may include one first light emitter EA1, one second light emitter EA2, and two third light emitters EA3. The first light emitter EA1 may be arranged at the upper left end of the unit light emitter. The second light emitter EA2 may be arranged at the lower left end of the unit light emitter. The two third light emitters EA3 may be arranged at the upper right end and the lower right end of the unit light emitter, respectively. However, the disclosure is not limited thereto.

In an embodiment, the first light emitter EA1 may have a rectangular shape. Referring to FIG. 6B, the first light emitter EA1 may have a rectangular shape including a first long side A1 extending in the first direction (e.g., the x direction or the −x direction), a second long side A2 extending in the first direction (e.g., the x direction or the −x direction), and short sides B1 extending in the second direction (e.g., the y direction or the −y direction). The third light emitter EA3 may also have a rectangular shape. Referring to FIG. 6C, the third light emitter EA3 at the lower right end may have a rectangular shape. The third light emitter EA3 at the lower right end may have a rectangular shape including a third long side A3 extending in the second direction (e.g., the y direction or the −y direction), a fourth long side A4 extending in the second direction (e.g., the y direction or the −y direction), and short sides B2 extending in the first direction (e.g., the x direction or the −x direction).

In an embodiment, the third light emitter EA3 arranged at the upper right end of the unit light emitter and the second light emitter EA2 may have a square shape. However, the disclosure is not limited thereto. In another embodiment, the third light emitter EA3 arranged at the upper right end of the unit light emitter and the second light emitter EA2 may have a rectangular shape with a small length difference between the long side and the short side. In other words, the third light emitter EA3 arranged at the upper right of the unit light emitter and the second light emitter EA2 may have a rectangular shape close to a square shape.

A first refractive layer 510 may be disposed over the first light emitter EA1, the second light emitter EA2, and the third light emitter EA3 to cover and surround each of the first light emitter EA1, the second light emitter EA2, and the third light emitter EA3 in a plan view. The first refractive layer 510 covering and surrounding the third light emitter EA3 at the upper right end of the unit light emitter and the second light emitter EA2 may be arranged such that the shortest lengths of parts of the first refractive layer 510 protruded from the sides included in the rectangular shapes of the third light emitter EA3 at the upper right end of the unit light emitter and the second light emitter EA2 may be equal to each other in a plan view. However, the disclosure is not limited thereto.

The first long side A1 included in the rectangular shape of the first light emitter EA1 may include a first portion a1 and a second portion a2. Also, the second long side A2 included in the rectangular shape of the first light emitter EA1 may include a third portion a3 and a fourth portion a4. The first refractive layer 510 may be arranged to surround the first light emitter EA1. A length t1 of a part of the first refractive layer 510 protruded from the first portion a1 of the first long side A1 in the second direction (e.g., the y direction or the −y direction) in the plan view and a length t2 of a part of the first refractive layer 510 protruded from the second portion a2 of the first long side A1 in the second direction (e.g., the y direction or the −y direction) in the plan view may be different from each other. FIG. 6B illustrates that the length t1 of a part of the first refractive layer 510 protruded from the first portion a1 of the first long side A1 in the second direction (e.g., the y direction or the −y direction) in the plan view is greater than the length t2 of a part of the first refractive layer 510 protruded from the second portion a2 of the first long side A1 in the second direction (e.g., the y direction or the −y direction) in the plan view; however, the disclosure is not limited thereto. In another embodiment, the length t1 of a part of the first refractive layer 510 protruded from the first portion a1 of the first long side A1 in the second direction (e.g., the y direction or the −y direction) in the plan view may be less than the length t2 of a part of the first refractive layer 510 protruded from the second portion a2 of the first long side A1 in the second direction (e.g., the y direction or the −y direction) in the plan view. Also, a length t3 of a part of the first refractive layer 510 protruded from the third portion a3 of the second long side A2 in the second direction (e.g., the y direction or the −y direction) in the plan view and a length t4 of a part of the first refractive layer 510 protruded from the fourth portion a4 of the second long side A2 in the second direction (e.g., the y direction or the −y direction) in the plan view may be different from each other. FIG. 6B illustrates that the length t3 of a part of the first refractive layer 510 protruded from the third portion a3 of the second long side A2 in the second direction (e.g., the y direction or the −y direction) in the plan view is less than the length t4 of a part of the first refractive layer 510 protruded from the fourth portion a4 of the second long side A2 in the second direction (e.g., the y direction or the −y direction) in the plan view; however, the disclosure is not limited thereto. In another embodiment, the length t3 of a part of the first refractive layer 510 protruded from the third portion a3 of the second long side A2 in the second direction (e.g., the y direction or the −y direction) in the plan view may be greater than the length t4 of a part of the first refractive layer 510 protruded from the fourth portion a4 of the second long side A2 in the second direction (e.g., the y direction or the −y direction) in the plan view.

The third long side A3 included in the rectangular shape of the third light emitter EA3 may include a fifth portion a5 and a sixth portion a6. Also, the fourth long side A4 included in the rectangular shape of the third light emitter EA3 may include a seventh portion a7 and an eighth portion a8. The first refractive layer 510 may be arranged to surround the third light emitter EA3 of the rectangular shape. A length t5 of a part of the first refractive layer 510 protruded from the fifth portion a5 of the third long side A3 in the first direction (e.g., the x direction or the −x direction) in the plan view and a length t6 of a part of the first refractive layer 510 protruded from the sixth portion a6 of the third long side A3 in the first direction (e.g., the x direction or the −x direction) in the plan view may be different from each other. FIG. 6C illustrates that the length t5 of a part of the first refractive layer 510 protruded from the fifth portion a5 of the third long side A3 in the first direction (e.g., the x direction or the −x direction) in the plan view is less than the length t6 of a part of the first refractive layer 510 protruded from the sixth portion a6 of the third long side A3 in the first direction (e.g., the x direction or the −x direction) in the plan view; however, the disclosure is not limited thereto. In another embodiment, the length t5 of a part of the first refractive layer 510 protruded from the fifth portion a5 of the third long side A3 in the first direction (e.g., the x direction or the −x direction) in the plan view may be greater than the length t6 length of a part of the first refractive layer 510 protruded from the sixth portion a6 of the third long side A3 in the first direction (e.g., the x direction or the −x direction) in the plan view. Also, a length t7 length of a part of the first refractive layer 510 protruded from the seventh portion a7 of the fourth long side A4 in the first direction (e.g., the x direction or the −x direction) in the plan view and a length t8 length of a part of the first refractive layer 510 protruded from the eighth portion a8 of the fourth long side A4 in the first direction (e.g., the x direction or the −x direction) in the plan view may be different from each other. FIG. 6C illustrates that the length t7 length of a part of the first refractive layer 510 protruded from the seventh portion a7 of the fourth long side A4 in the first direction (e.g., the x direction or the −x direction) in the plan view is greater than the length t8 length of a part of the first refractive layer 510 protruded from the eighth portion a8 of the fourth long side A4 in the first direction (e.g., the x direction or the −x direction) in the plan view; however, the disclosure is not limited thereto. In another embodiment, the length t7 length of a part of the first refractive layer 510 protruded from the seventh portion a7 of the fourth long side A4 in the first direction (e.g., the x direction or the −x direction) in the plan view may be less than the length t8 length of a part of the first refractive layer 510 protruded from the eighth portion a8 of the fourth long side A4 in the first direction (e.g., the x direction or the −x direction) in the plan view.

Referring to FIG. 7, the unit light emitter arranged in the display area DA may include three third light emitters EA3. The three third light emitters EA3 may be arranged at the upper right end and/or the lower right end. The position and shape of the first light emitter EA1, the second light emitter EA2, and the third light emitter EA3 at the upper right end of the unit light emitter of FIG. 7 may be the same as those of FIG. 6A. The number and shape of the third light emitters EA3 at the lower right end of the unit light emitter may be different from those of FIG. 6A. The two third light emitters EA3 arranged at the lower right end may be obtained by dividing the third light emitter EA3 arranged at the lower right end of FIG. 6A, and the third light emitters EA3 may have a shape close to a square shape. When the third light emitter EA3 at the lower right end has a square shape, the shortest lengths of parts of the first refractive layer 510 protruded from the sides included in the square shape of the third light emitter EA3 and the first refractive layer 510 covering and surrounding the third light emitter EA3 in a plan view may be equal to each other.

In the related art, in order to improve the light extraction in a display apparatus, a first refractive layer is patterned to be arranged outside a light emitter in a plan view, and a high refractive index flat layer (“HRF”) is disposed over the first refractive layer. By arranging the first refractive layer outside the light emitter, side light emitted from the light emitter is reflected from an inclined surface of the first refractive layer and thus a light path may be changed from the side light to front light. The light extraction efficiency of the display apparatus may be improved by improving the front light emission of the light emitter.

However, in the light extraction efficiency improvement structure of the related art, a stain due to the step of the HRF disposed over the first refractive layer is visually recognized, the price thereof increases due to the addition of the process or material of the HRF, and a light extraction efficiency improvement is verified only in a pentile pixel structure. Thus, it is difficult to apply to a low-cost model, and it is difficult to apply the light extraction efficiency improvement structure of the related art to an s-stripe pixel structure. In the s-stripe pixel structure, the shape of pixels may be a rectangular shape in which the long side and the short side have different lengths.

In an embodiment, the first refractive layer 510 may be arranged not only to cover the outside of the light emitter EA but also to cover the light emitter EA itself. In other words, the first refractive layer 510 may be arranged to cover and surround each of the light emitters EA. In the case of the light emitter EA of the pixel PX having a rectangular shape with a great length difference between the long side and the short side in the s-stripe pixel structure, a portion of the first refractive layer 510 arranged to cover and surround the long side included in the rectangular shape of the light emitter EA may be arranged apart from the long side. Because a portion of the first refractive layer 510 is arranged apart from the light emitter EA, the influence of the first refractive layer 510 on the long side of the rectangular shape of the light emitter EA may be reduced. The influences of the first refractive layer 510 on the short side and the long side of the rectangular shape of the light emitter EA may be similar to each other. Thus, the light extraction efficiency may be effectively improved even in the s-stripe asymmetrical pixel structure.

Also, in the case of the light emitter EA of the pixel having a rectangular shape with a great length difference between the long side and the short side in the s-stripe pixel structure, the light emitter EA may be divided to form light emitters EA having a shape close to a square shape, thereby improving the light extraction efficiency.

In an embodiment, a third touch insulating layer 430 may be arranged between the light emitters EA while being spaced apart from the first refractive layer 510 covering and surrounding each of the light emitters EA in a plan view. The third touch insulating layer 430 and the refractive layer 510 may be arranged on the same layer and may include the same material. The third touch insulating layer 430 may contact a partial area of the first refractive layer 510 covering and surrounding the first light emitter EA1 having a rectangular shape and a partial area of the first refractive layer 510 covering and surrounding the third light emitter EA3 having a rectangular shape. Particularly, the end (or edge) of a portion of the first refractive layer 510 covering and surrounding the first portion a1 of the first long side A1 of the first light emitter EA1 in a plan view may contact the third touch insulating layer 430. In other words, the end (or edge) of a portion of the first refractive layer 510 covering and surrounding the first portion a1 of the first long side A1 of the first light emitter EA1 in a plan view may be integrated with the third touch insulating layer 430. Also, the end (or edge) of a portion of the first refractive layer 510 covering and surrounding the fourth portion a4 of the second long side A2 of the first light emitter EA1 in a plan view may contact the third touch insulating layer 430. In other words, the end (or edge) of a portion of the first refractive layer 510 covering and surrounding the fourth portion a4 of the second long side A2 of the first light emitter EA1 in a plan view may be integrated with the third touch insulating layer 430. The end (or edge) of a portion of the first refractive layer 510 covering and surrounding the sixth portion a6 of the third long side A3 of the third light emitter EA3 in a plan view may contact the third touch insulating layer 430. In other words, the end (or edge) of a portion of the first refractive layer 510 covering and surrounding the sixth portion a6 of the third long side A3 of the third light emitter EA3 in a plan view may be integrated with the third touch insulating layer 430. The end (or edge) of a portion of the first refractive layer 510 covering and surrounding the seventh portion a7 of the fourth long side A4 of the third light emitter EA3 in a plan view may contact the third touch insulating layer 430. In other words, the end (or edge) of a portion of the first refractive layer 510 covering and surrounding the seventh portion a7 of the fourth long side A4 of the third light emitter EA3 in a plan view may be integrated with the third touch insulating layer 430.

FIG. 8 is a cross-sectional view schematically illustrating a display apparatus according to an embodiment. More particularly, FIG. 8 corresponds to a cross-sectional view of certain layers of the display apparatus taken along line II-II′ of FIG. 6A.

Referring to FIG. 8, a buffer layer 111 formed to prevent impurities from penetrating into a semiconductor layer of a thin film transistor may be disposed over a substrate 100.

The substrate 100 may be formed of various materials such as glass materials, metal materials, or plastic materials. According to an embodiment, the substrate 100 may be a flexible substrate and may include, for example, a polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate.

The buffer layer 111 may include an inorganic insulating material such as silicon nitride or silicon oxide and may include a single layer or multiple layers. A barrier layer (not illustrated) may be further included between the substrate 100 and the buffer layer 111. The barrier layer may prevent or minimize the penetration of impurities from the substrate 100 or the like into the semiconductor layer. The barrier layer may include an inorganic material such as oxide or nitride, an organic material, or an organic/inorganic composite and may include a single-layer or multiple-layer structure of an inorganic material and an organic material.

A thin film transistor TFT, a storage capacitor Cst, and an organic light emitting diode 200 electrically connected to the thin film transistor TFT may be disposed over the substrate 100. When the organic light emitting diode 200 is referred to as being electrically connected to the thin film transistor TFT, a pixel electrode 211 may be understood as being electrically connected to the thin film transistor TFT. The thin film transistor TFT may be the driving thin film transistor T1 of FIGS. 4 and 5.

The thin film transistor TFT may include a semiconductor layer 132, a gate electrode 134, a source electrode 136S, and a drain electrode 136D. The semiconductor layer 132 may include an oxide semiconductor material. The semiconductor layer 132 may include amorphous silicon, polysilicon, or an organic semiconductor material. In consideration of adhesion with an adjacent layer, surface flatness of a stacked layer, and processability, the gate electrode 134 may include a single layer or multiple layers including, for example, one or more of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

A first insulating layer 112 including an inorganic material such as silicon oxide, silicon nitride, and/or silicon oxynitride may be arranged between the semiconductor layer 132 and the gate electrode 134. A second insulating layer 113 including an inorganic material such as silicon oxide, silicon nitride, and/or silicon oxynitride and a third insulating layer 114 may be arranged between the gate electrode 134 and the source electrode 136S and the drain electrode 136D. The source electrode 136S and the drain electrode 136D may be electrically connected to the semiconductor layer 132 respectively through contact holes defined in the second insulating layer 113 and the third insulating layer 114.

The source electrode 136S and the drain electrode 136D may include a single layer or multiple layers including one or more of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In an embodiment, for example, the source electrode 136S and the drain electrode 136D may include a multilayer structure of Ti/Al/Ti.

The storage capacitor Cst may include a first electrode CE1 and a second electrode CE2 overlapping each other with the second insulating layer 113 therebetween. The storage capacitor Cst may overlap the thin film transistor TFT. FIG. 8 illustrates that the gate electrode 134 of the thin film transistor TFT is the first electrode CE1 of the storage capacitor Cst. In another embodiment, the storage capacitor Cst may not overlap the thin film transistor TFT. That is, the first electrode CE1 of the storage capacitor Cst may be disposed over the first insulating layer 112 as a separate component from the gate electrode 134 of the thin film transistor TFT. The storage capacitor Cst may be covered by the third insulating layer 114.

A pixel circuit including the thin film transistor TFT and the storage capacitor Cst may be covered by a first planarization layer 115 and a second planarization layer 116. The first planarization layer 115 and the second planarization layer 116 may be organic insulation layers as planarization insulation layers. The first planarization layer 115 and the second planarization layer 116 may include an organic insulating material such as a general-purpose polymer such as polymethylmethacrylate (“PMMA”) or polystyrene (“PS”), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or any blend thereof. In an embodiment, the first planarization layer 115 and the second planarization layer 116 may include polyimide.

A display device, for example, the organic light emitting diode 200, may be disposed over the second planarization layer 116. The organic light emitting diode 200 may include a pixel electrode 211, an intermediate layer 231, and an opposite electrode 251.

The pixel electrode 211 may be disposed over the second planarization layer 116 and may be connected to the thin film transistor TFT through a connection electrode 181 over the first planarization layer 115. Lines 183 such as a data line DL and a driving voltage line PL may be disposed over the first planarization layer 115.

The pixel electrode 211 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In other embodiments, the pixel electrode 211 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. In other embodiments, the pixel electrode 211 may further include a layer formed of ITO, IZO, ZnO, or In₂O₃ over/under the reflective layer. In an embodiment, for example, the pixel electrode 211 may include ITO/Ag/ITO.

A pixel definition layer 117 may be disposed over the second planarization layer 116. The pixel definition layer 117 may cover the edge of the pixel electrode 211 and may define a pixel by including a first opening 1170P through which a portion of the pixel electrode 211 is exposed. The pixel definition layer 117 may increase the distance between the edge of the pixel electrode 211 and the opposite electrode 251 to prevent an arc or the like from occurring at the edge of the pixel electrode 211. The pixel definition layer 117 may be formed of, for example, an organic material such as polyimide or hexamethyldisiloxane (“HMDSO”).

The intermediate layer 231 may include an emission layer. The emission layer may include a high-molecular-weight organic material or a low-molecular-weight organic material for emitting light of a certain color. In an embodiment, the intermediate layer 231 may include a first functional layer disposed under the emission layer and/or a second functional layer disposed over the emission layer. The first functional layer and/or the second functional layer may include a layer integrated over a plurality of pixel electrodes 211 or may include a layer patterned to correspond to each of a plurality of pixel electrodes 211.

The first functional layer may include a single layer or multiple layers. In an embodiment, for example, when the first functional layer is formed of a high-molecular-weight organic material, the first functional layer may include a hole transport layer (“HTL”) that is a single-layer structure and may be formed of polyethylene dihydroxythiophene (poly-(3,4)-ethylene-dihydroxy thiophene (“PEDOT”)) or polyaniline (“PANI”). When the first functional layer is formed of a low-molecular-weight organic material, the first functional layer may include a hole injection layer (“HIL”) and a hole transport layer (HTL).

The second functional layer may be omitted. In an embodiment, for example, when the first functional layer and the emission layer are formed of a high-molecular-weight organic material, the second functional layer may be formed to improve the characteristics of the organic light emitting diode. The second functional layer may include a single layer or multiple layers. The second functional layer may include an electron transport layer (“ETL”) and/or an electron injection layer (“EIL”).

The opposite electrode 251 may be arranged to face the pixel electrode 211 with the intermediate layer 231 therebetween. The opposite electrode 251 may include a conductive material having a low work function. In an embodiment, for example, the opposite electrode 251 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the opposite electrode 251 may further include a layer such as ITO, IZO, ZnO, or In₂O₃ over the (semi)transparent layer including the above material.

The opposite electrode 251 may be disposed over the intermediate layer 231 and the pixel definition layer 117. In the display area DA, the opposite electrode 251 may be integrally formed in a plurality of organic light emitting diodes 200 to face a plurality of pixel electrodes 211.

An encapsulation layer 300, an input sensing layer 400, a refractive layer 500, a polarization layer 600, an adhesive layer 700, and a window 800 may be disposed over the opposite electrode 251. This will be described below in more detail.

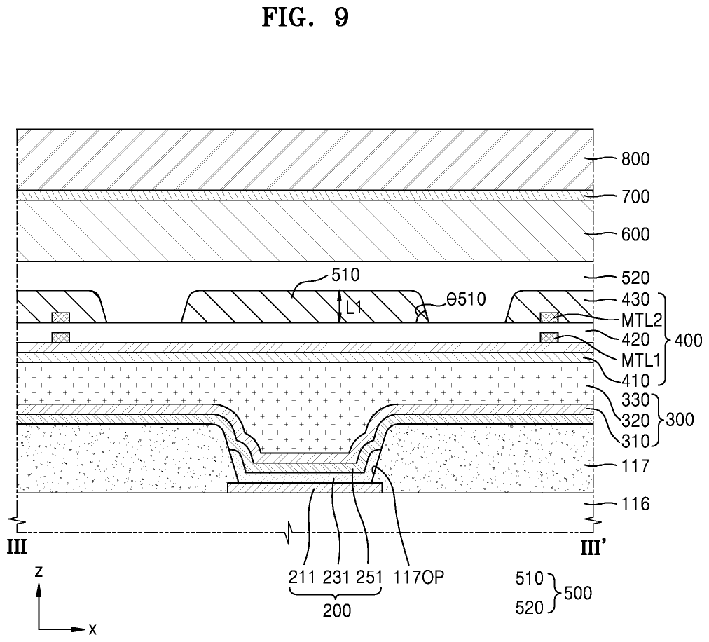

FIG. 9 is a cross-sectional view schematically illustrating a display apparatus according to an embodiment. Particularly, FIG. 9 is a schematic cross-sectional view of the display apparatus taken along line III-III′ of FIG. 6A.

In an embodiment, an encapsulation layer 300 may be disposed over the opposite electrode 251. The encapsulation layer 300 may protect the organic light emitting diode 200 from external moisture or oxygen. The encapsulation layer 300 may have a multilayer structure. In an embodiment, for example, the encapsulation layer 300 may include a first inorganic encapsulation layer 310, an organic encapsulation layer 320, and a second inorganic encapsulation layer 330. Because the encapsulation layer 300 is formed to have a multilayer structure, even when a crack occurs in the encapsulation layer 300, the crack may not be connected between the first inorganic encapsulation layer 310 and the organic encapsulation layer 320 or between the organic encapsulation layer 320 and the second inorganic encapsulation layer 330 and thus formation of a path through which external moisture or oxygen penetrates into the display area DA may be prevented or minimized. In other embodiments, the number of organic encapsulation layers, the number of inorganic encapsulation layers, and the stacking order thereof may be modified.

The first inorganic encapsulation layer 310 may cover the opposite electrode 251 and may include one or more inorganic insulating materials such as aluminum oxide, titanium oxide, tantalum oxide, hafnium oxide, zinc oxide, silicon oxide, silicon nitride, and/or silicon oxynitride. Because the first inorganic encapsulation layer 310 is formed along the structure thereunder, the upper surface thereof may not be flat.

The organic encapsulation layer 320 may cover the first inorganic encapsulation layer 310 and may have a sufficient thickness. The upper surface of the organic encapsulation layer 320 may be substantially flat throughout the display area DA. The organic encapsulation layer 320 may include polyethyleneterephthalate, polyethylenenaphthalate, polycarbonate, polyimide, polyethylenesulfonate, polyoxymethylene, polyarylate, hexamethyldisiloxane, acrylic resin (e.g., polymethylmethacrylate or polyacrylic acid), or any combination thereof.

The second inorganic encapsulation layer 330 may cover the organic encapsulation layer 320 and may include one or more inorganic insulating materials such as aluminum oxide, titanium oxide, tantalum oxide, hafnium oxide, zinc oxide, silicon oxide, silicon nitride, and/or silicon oxynitride. The second inorganic encapsulation layer 330 may extend outside the organic encapsulation layer 320 and contact the first inorganic encapsulation layer 310 in the peripheral area PA, thereby preventing the organic encapsulation layer 320 from being exposed to the outside.

Moreover, in the process of forming the encapsulation layer 300, the structures thereunder may be damaged. In an embodiment, for example, in the process of forming the first inorganic encapsulation layer 310, a layer directly under the first inorganic encapsulation layer 310 may be damaged. Thus, in order to prevent the structure thereunder from being damaged in the process of forming the encapsulation layer 300, at least one capping layer and/or a protection layer may be arranged between the opposite electrode 251 and the encapsulation layer 300. The capping layer and/or the protection layer may include an inorganic material.

An input sensing layer 400 may be disposed over the organic light emitting diode 200, for example, over the encapsulation layer 300. The input sensing layer 400 may be configured to obtain coordinate information according to an external input, for example, a touch event of an object such as a finger or a stylus pen. The input sensing layer 400 may include a sensing electrode and/or a trace line. The input sensing layer 400 may be configured to sense an external input by a mutual cap method or a self cap method.

The input sensing layer 400 may include a first conductive layer MTL1 and a second conductive layer MTL2 including a sensing electrode and/or a trace line. A first touch insulating layer 410 may be arranged between the encapsulation layer 300 and the first conductive layer MTL1, and a second touch insulating layer 420 may be arranged between the first conductive layer MTL1 and the second conductive layer MTL2. A third touch insulating layer 430 may be disposed over the second conductive layer MTL2 and the second touch insulating layer 420.

The first conductive layer MTL1 and the second conductive layer MTL2 may include a conductive material. The conductive material may include molybdenum (Mo), aluminum (Al), copper (Cu), titanium (Ti), or the like and may include a single layer or multiple layers including the above material. In some embodiments, each of the first conductive layer MTL1 and the second conductive layer MTL2 may have a structure in which a titanium layer, an aluminum layer, and a titanium layer are sequentially stacked (Ti/Al/Ti).

Each of the first touch insulating layer 410, the second touch insulating layer 420, and the third touch insulating layer 430 may include an inorganic insulating material and/or an organic insulating material. The inorganic insulating material may include silicon oxide, silicon oxynitride, silicon nitride, or the like. The organic insulating material may include an acryl-based organic material or an imide-based organic material.

Not only the third touch insulating layer 430 but also a first refractive layer 510 may be disposed over the second conductive layer MTL2 and the second touch insulating layer 420. The third touch insulating layer 430 and the first refractive layer 510 may be arranged on the same layer and may include the same material. The third touch insulating layer 430 may be arranged to cover the second conductive layer MTL2. The first refractive layer 510 may be arranged to cover the light emitter EA. In other words, the first refractive layer 510 may be arranged to surround the light emitter EA. A thickness L1 of the first refractive layer 510 in a direction perpendicular to the substrate 100 (e.g., the z direction or the −z direction) may be about 1.5 micrometers (μm) to about 5 μm. The side surface of the first refractive layer 510 may be formed to be inclined. An angle 8510 between the side surface of the first refractive layer 510 and a layer disposed thereunder may be about 30° to about 90°. Because the second touch insulating layer 420 may be disposed under the first refractive layer 510, the angle 8510 between the side surface of the first refractive layer 510 and the second touch insulating layer 420 disposed thereunder may be about 30° to about 90°. However, the disclosure is not limited thereto.

A second refractive layer 520 may be disposed over the first refractive layer 510. The second refractive layer 520 may be an adhesive layer disposed under a polarization layer 600. The adhesive layer may include at least one of an acrylate-based resin, a silicon-based resin, a urethane-based resin, an epoxy-based resin, a rubber-based resin, or a polyester-based resin and may include one or two or more of the same-series resins.

The first refractive layer 510 may have a first refractive index, and the second refractive layer 520 may have a second refractive index. The first refractive index of the first refractive layer 510 may be greater than the second refractive index of the second refractive layer 520. Particularly, the difference between the first refractive index of the first refractive layer 510 and the second refractive index of the second refractive layer 520 may be about 0.04 to about 1. However, the disclosure is not limited thereto.

In the related art, an HRF is disposed over a first refractive layer. In an embodiment, instead of the HRF, the second refractive layer 520 may be disposed over the first refractive layer 510. The second refractive layer 520 may be an adhesive layer disposed under a polarization layer 600. By using the adhesive layer disposed under the polarization layer 600 as the second refractive layer 520, the cost of the material or process of the HRF may be solved, and the light extraction efficiency improvement structure according to an embodiment may be applied to a low-cost model such as a watch.

In an embodiment, a polarization layer 600 may be disposed over the second refractive layer 520. The polarization layer 600 may transmit only light vibrating in the same direction as a polarization axis among the light emitted from the display device of the display device layer DPL and may absorb or reflect light vibrating in other directions. The polarization layer 600 may include a phase retarder and/or a polarizer. Also, the polarization layer 600 may include a black matrix and/or a color filter. Although not illustrated, the refractive layer 500 and the polarization layer 600 may be adhered by an adhesive such as an optically clear adhesive (OCA).

A window 800 may be disposed over the polarization layer 600, and an adhesive layer 700 such as an optically clear adhesive (OCA) may be arranged therebetween.

In the related art, in order to improve the light extraction in a display apparatus, a first refractive layer is patterned to be arranged outside a light emitter, and an HRF is disposed over the first refractive layer. However, the light extraction improvement structure of the related art is difficult to apply to an s-stripe pixel structure and is difficult to apply to a low-cost structure due to the cost of the material or process of the HRF.

According to an embodiment, the first refractive layer 510 may be patterned to surround each of the light emitters EA. When the light emitter EA of an s-stripe pixel has an asymmetrical rectangular shape, a portion of the first refractive layer 510 arranged to surround the long side included in the rectangular shape of the light emitter EA may be arranged apart from the light emitter EA. Because a portion of the first refractive layer 510 covering and surrounding the long side of the rectangular shape of the light emitter EA of the pixel PX in a plan view is arranged apart therefrom, the influence of the first refractive layer 510 on the long side of the light emitter EA may be reduced and the light extraction of the s-stripe pixel may be improved due to this structure. In other words, the light extraction of the s-stripe pixel may be improved by asymmetrically patterning the first refractive layer 510 to surround the light emitter EA.

Also, instead of the HRF, an adhesive layer disposed under the polarization layer 600 may be used as the second refractive layer 520 over the first refractive layer 510. By using the adhesive layer as the second refractive layer 520, the light extraction improvement structure according to an embodiment may also be applied to a low-cost model.

According to embodiments, the light extraction efficiency of the display apparatus may be improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a first light emitter disposed over the substrate; and
a first refractive layer patterned to cover and surround the first light emitter in a plan view,
wherein the first light emitter has a rectangular shape comprising a first long side extending in a first direction, a second long side extending in the first direction, and short sides extending in a second direction intersecting the first direction,
the first long side comprises a first portion and a second portion,
the second long side comprises a third portion and a fourth portion, and
a length of a part of the first refractive layer protruded from the first portion in the second direction in the plan view and a length of a part of the first refractive layer protruded from the second portion in the second direction in the plan view are different from each other.

2. The display apparatus of claim 1, wherein a length of a part of the first refractive layer protruded from the third portion in the second direction in the plan view and a length of a part of the first refractive layer protruded from the fourth portion in the second direction in the plan view are different from each other.

3. The display apparatus of claim 1, wherein the first light emitter emits red light.

4. The display apparatus of claim 1, further comprising:
a second light emitter disposed over the substrate,
wherein the first refractive layer is further patterned to cover and surround the second light emitter in the plan view.

5. The display apparatus of claim 4, wherein the second light emitter emits green light.

6. The display apparatus of claim 1, further comprising:
two third light emitters disposed over the substrate,
wherein the first refractive layer is further patterned to cover and surround the two third light emitters in the plan view.

7. The display apparatus of claim 6, wherein one of the two third light emitters has a rectangular shape comprising a third long side extending in the second direction, a fourth long side extending in the second direction, and short sides extending in the first direction,
the third long side comprises a fifth portion and a sixth portion,
the fourth long side comprises a seventh portion and an eighth portion, and
a length of a part of the first refractive layer protruded from the fifth portion in the first direction in the plan view and a length of a part of the first refractive layer protruded from the sixth portion in the first direction in the plan view are different from each other.

8. The display apparatus of claim 7, wherein a length of a part of the first refractive layer protruded from the seventh portion in the first direction in the plan view and a length of a part of the first refractive layer protruded from the eighth portion in the first direction in the plan view are different from each other.

9. The display apparatus of claim 6, wherein the third light emitters emit blue light.

10. The display apparatus of claim 1, wherein a thickness of the first refractive layer is about 1.5 micrometers (μm) to about 5 μm.

11. The display apparatus of claim 1, wherein an angle between an inclined side surface of the first refractive layer and a layer disposed thereunder is about 30° to about 90°.

12. The display apparatus of claim 1, further comprising a second refractive layer directly disposed over the first refractive layer.

13. The display apparatus of claim 12, wherein the first refractive layer and the second refractive layer have a first refractive index and a second refractive index, respectively,
the first refractive index is greater than the second refractive index, and
a difference between the first refractive index and the second refractive index is about 0.04 to about 1.

14. The display apparatus of claim 1, further comprising three third light emitters disposed over the substrate.

15. A display apparatus comprising:
a substrate;
a light emitter disposed over the substrate;
an encapsulation layer encapsulating the first light emitter;
an input sensing layer disposed over the encapsulation layer and comprising a conductive layer and a touch insulating layer covering the first conductive layer; and
a first refractive layer patterned to cover and surround the first light emitter in a plan view,
wherein the touch insulating layer and the first refractive layer comprise a same material.

16. The display apparatus of claim 15, wherein the first light emitter has a rectangular shape comprising a first long side extending in a first direction, a second long side extending in the first direction, and short sides extending in a second direction intersecting the first direction,
the first long side comprises a first portion and a second portion,
the second long side comprises a third portion and a fourth portion, and
a length of a part of the first refractive layer protruded from the first portion in the second direction in the plan view and a length of a part of the first refractive layer protruded from the second portion in the second direction in the plan view are different from each other.

17. The display apparatus of claim 16, wherein an end of a portion of the first refractive layer covering and surrounding the first portion of the first long side of the first light emitter in the plan view contacts the touch insulating layer.

18. The display apparatus of claim 16, wherein an end of a portion of the first refractive layer covering and surrounding the fourth portion of the second long side of the first light emitter in the plan view contacts the touch insulating layer.

19. The display apparatus of claim 15, further comprising a second refractive layer directly disposed over the first refractive layer.

20. The display apparatus of claim 19, wherein the first refractive layer and the second refractive layer have a first refractive index and a second refractive index, respectively,
the first refractive index is greater than the second refractive index, and
a difference between the first refractive index and the second refractive index is about 0.04 to about 1.
